(19) United States
(12) Patent Application Publication
(10) Pub. No.: US 2005/0167083 A1
(43) Pub. Date: Aug. 4, 2005

(54) Heat sink including redundant fan sinks

(76) Inventors: Christian L. Belady, McKinney, TX (US); Glenn C. Simon, Auburn, CA (US); Christopher G. Malone, Loomis, CA (US); Shaun L. Harris, McKinney, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/769,006

(22) Filed: Jan. 29, 2004

(51) Int. Cl. H05K 7/20

(52) U.S. Cl. 165/80.3; 361/704

(57) ABSTRACT

A cooling device for electronic devices is built comprising at least two fan sinks thermally coupled together such that when one fan sink fails, the remaining fan sinks are able to compensate for the failed fan sink. Optionally, the remaining fan sinks may be controlled to speed up upon detection of a failure, increasing their cooling capacity to compensate for the failed fan sink. Also optionally, a thermal coupling device such as heat pipes may be used as part of the thermal coupling between the fan sinks to increase the cooling efficiency of the remaining fan sinks to the device or devices closest to the failed fan sink. Also optionally, the thermal coupling device may be configured to allow some flexibility in the cooling device assembly allowing for the cooling of non-coplanar electronic devices.

### FIELD OF THE INVENTION

The present invention relates generally to the field of heat sinks and more specifically to the field of fan sink designs with redundancy.

### BACKGROUND OF THE INVENTION

Modern electronic devices, such as microprocessors, not only generate large amounts of heat during operation, but are also temperature sensitive. Most integrated circuits run at slower speeds as temperature increases, and also failure mechanisms such as electromigration increase as temperature increases. Thus, the art of cooling electronic devices to a temperature within their operating range is critical to the proper operation of computers and other large electronic devices.

One common configuration used for cooling electronic devices is the fan sink. A fan sink is created by constructing a heat sink substantially surrounding a fan, configured such that when the fan is operating it creates substantial airflow over the heat sink. Often the fan sink is attached to an electronic device such as a microprocessor through the use of a heat spreader. This heat spreader allows the heat generated by the microprocessor to spread evenly to the fan sink without the creation of substantial hot spots.

However one problem inherent with fan sinks is that since they typically are only used where their cooling capacity is necessary, if the fan fails, the electronic device will overheat, sometimes catastrophically.

### SUMMARY OF THE INVENTION

A cooling device for electronic devices is built comprising at least two fan sinks thermally coupled together such that when one fan sink fails, the remaining fan sinks are able to compensate for the failed fan sink. Optionally, the remaining fan sinks may be controlled to speed up upon detection of a failure, increasing their cooling capacity to compensate for the failed fan sink. Also optionally, a thermal coupling device such as heat pipes may be used as part of the thermal coupling between the fan sinks to increase the cooling efficiency of the remaining fan sinks to the device or devices closest to the failed fan sink. Also optionally, the thermal coupling device may be configured to allow some flexibility in the cooling device assembly allowing for the cooling of non-coplanar electronic devices.

Other aspects and advantages of the present invention will become apparent from the following detailed description, taken in conjunction with the accompanying drawings, illustrating by way of example the principles of the invention.

### BRIEF DESCRIPTION OF THE DRAWINGS

FIG. 1 is a front view of a redundant fan sink design including heat pipes according to the present invention configured to cool a single electronic device.

FIG. 2 is a front view of a redundant fan sink design including heat pipes and a double fan sink according to the present invention configured to cool multiple electronic devices.

FIG. 3 is a front view of a redundant fan sink design including flexible heat pipes according to the present invention configured to cool multiple electronic devices.

### DETAILED DESCRIPTION

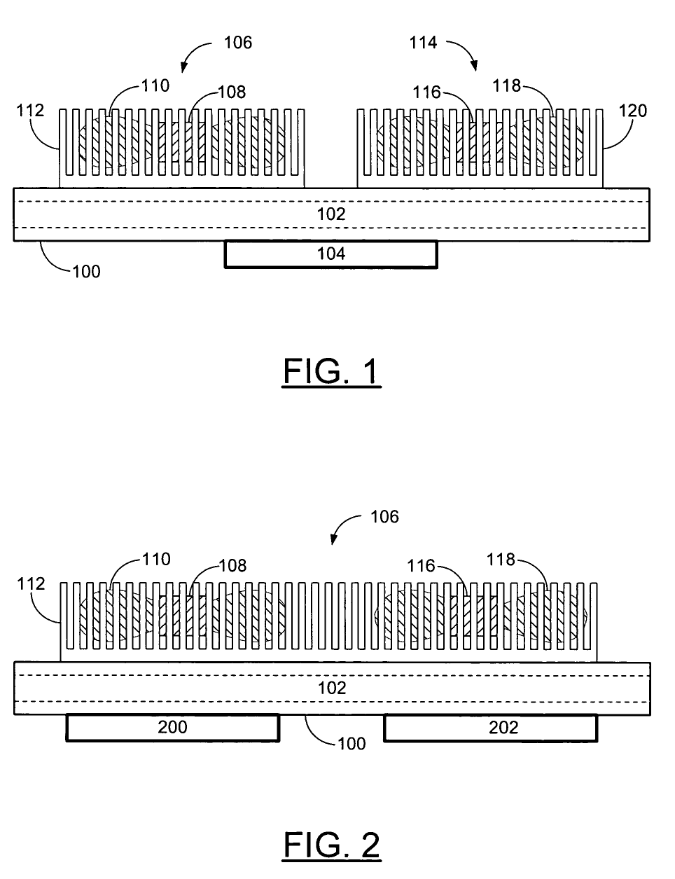

FIG. 1 is a front view of a redundant fan sink design including heat pipes according to the present invention configured to cool a single electronic device. In this example embodiment of the present invention a heat sink is built including two fan sinks. Other embodiments of the present invention may include any number of additional fan sinks to the two shown in FIG. 1. An electronic device 104 that generates heat is thermally and mechanically coupled to a heat spreader 100. In this example embodiment of the present invention, the heat spreader 100 includes at least one heat pipe 102 to increase the efficiency of the heat spreader 100 in eliminating hot spots over the electronic device 104. Other embodiments of the present invention may not require the use of heat pipes. A first fan sink 106 comprising a first heat sink 112 surrounding a first fan is thermally and mechanically coupled to the heat spreader 100. The first fan includes a first motor 108 and first fan blades 110. A second fan sink 114 comprising a second heat sink 120 surrounding a second fan is also thermally and mechanically coupled to the heat spreader 100. The second fan includes a second motor 116 and second fan blades 118. In this example embodiment of the present invention, a single fan sink is sufficient to cool the electronic device 104, however two fan sinks are used for greater cooling. When one fan sink fails, the remaining fan sink is sufficient to keep the temperature of the electronic device 104 within design limits.

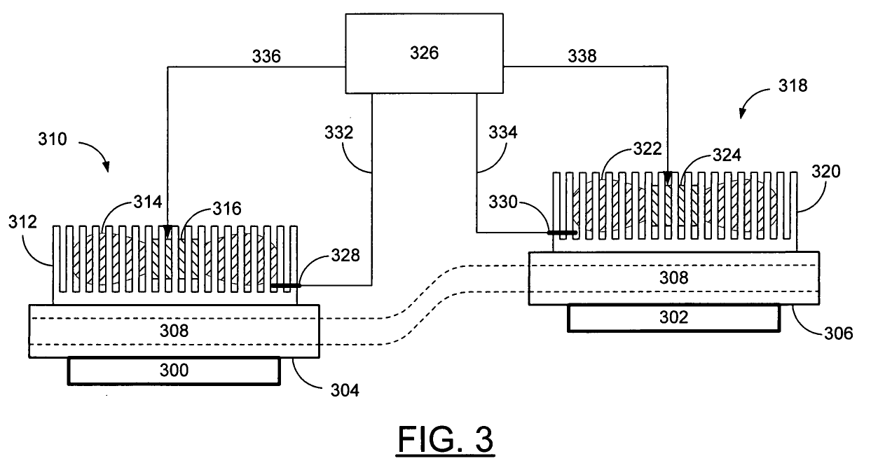

FIG. 2 is a front view of a redundant fan sink design including heat pipes and a double fan sink according to the present invention configured to cool multiple electronic devices. In this example embodiment of the present invention a heat sink is built including a double fan sink. Those of skill in the art will recognize that a wide variety of fan sinks with multiple fans may be build within the scope of the present invention. While this embodiment of the present invention shows a double fan sink, any number of fans may be used within a single surrounding heat sink within the scope of the present invention. Other embodiments of the present invention may include any number of additional fan sinks to the single double fan sink shown in FIG. 2. A first electronic device 200 and a second electronic device 202 that generate heat are thermally and mechanically coupled to a heat spreader 100. Those of skill in the art will recognize that heat spreaders may be made out of a wide variety of materials, including aluminum and copper, within the scope of the present invention. In this example embodiment of the present invention, the heat spreader 100 includes at least one heat pipe 102 to increase the efficiency of the heat spreader 100 in eliminating hot spots over the electronic devices 200, 202. Other embodiments of the present invention may not require the use of heat pipes, or may use other equivalent thermally conductive devices. A double fan sink 106 comprising a double wide heat sink 112 surrounding a first fan and a second fan is thermally and mechanically coupled to the heat spreader 100. The first fan includes a first motor 108 and first fan blades 110. The second fan includes a second motor 116 and second fan blades 118. In this example embodiment of the present invention, a single fan is sufficient to cool the electronic devices 200, 202, however two fans are used for greater cooling. When one fan fails, the remaining fan is sufficient to keep the temperature of the electronic devices 200, 202 within design limits.

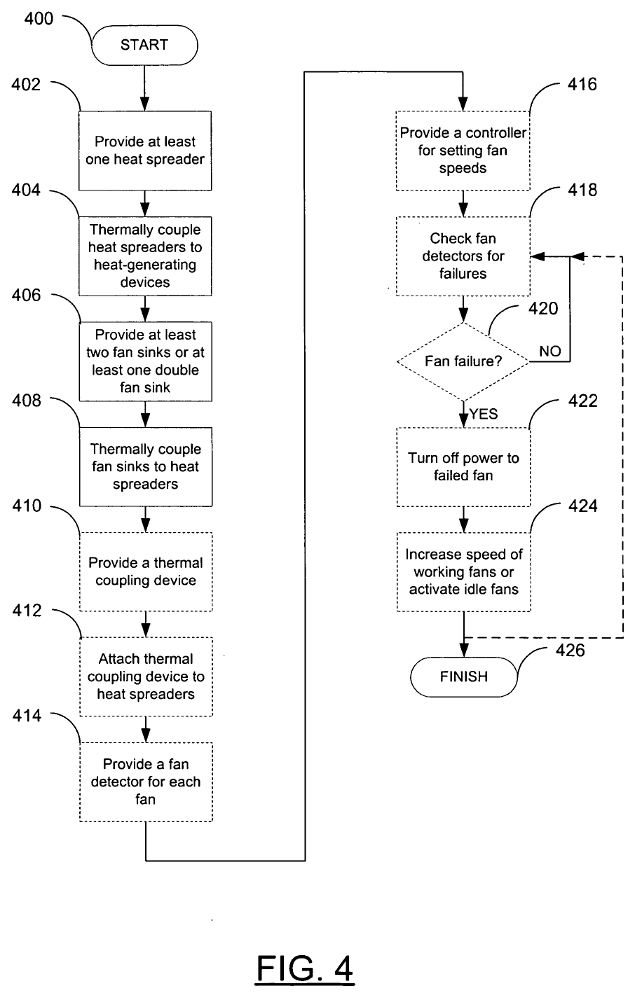

FIG. 3 is a front view of a redundant fan sink design including flexible heat pipes according to the present invention configured to cool multiple electronic devices. In this example embodiment of the present invention a heat sink is built including two fan sinks. Other embodiments of the present invention may include any number of additional fan sinks to the two shown in FIG. 3. A first electronic device 300 and a second electronic device 302 that generate heat are thermally and mechanically coupled to a first heat spreader 304, and a second heat spreader 306 respectively. The first and second heat spreaders 304, 306 include at least one heat pipe 308 thermally coupling the first and second heat spreaders 304, 306. A first fan sink 310 comprising a first heat sink 312 surrounding a first fan is thermally and mechanically coupled to the first heat spreader 304. The first fan includes a first motor 316 and first fan blades 314. A second fan sink 318 comprising a second heat sink 320 surrounding a second fan is thermally and mechanically coupled to the second heat spreader 306. The second fan includes a second motor 324 and second fan blades 322. In this example embodiment of the present invention, a single fan sink is sufficient to cool the electronic devices 300, 302, however since the two electronic devices are non-coplanar two separate heat spreaders are used. These two heat spreaders are thermally coupled with a thermal coupling device 308 such that when one fan sink fails, the remaining fan sink is sufficient to keep the temperature of the electronic devices 300, 302 within design limits by transferring heat from the heat spreader of the failed fan sink to the heat spreader of the working fan sink. In this example embodiment of the present invention a heat pipe is shown as the thermal coupling device 308, however, many other thermal coupling devices such as carbon fiber, a heat conducting fabric, copper straps or braids, or other equivalent thermally conductive materials. In some example embodiments of the present invention, one or more fans may remain idle until a fan failure is detected, and only activated at that time.

In this example embodiment of the present invention a controller 326 is included to control fan speed of the fan sinks. A first fan detector 328 is used to detect proper operation of the first fan sink 310 and a second fan detector 330 is used to detect proper operation of the second fan sink 318. Those of skill in the art will recognize that there are numerous ways to detect proper operation of the fans. Thermocouples may be used to detect rising temperatures in the heat sinks. Some fans include fan speed outputs that may be used to determine proper operation of the fans, and also to determine fan speed. Even something as simple as a switch that is pushed to one state by the airflow of a properly operating fan, and releases to a second state when the airflow is insufficient may be used to detect proper fan operation. In the present invention, “fan detector” is used as a generic term to describe any device capable of detecting failure of a fan.

In this example embodiment of the present invention, the controller 326 includes a first output 336 configured to control the fan speed of the first fan, and a second output 338 configured to control the fan speed of the second fan. The controller 326 receives fan failure information from the first fan detector 328 through a first input 332 and the second fan detector 330 through a second input 334. When one of the fans fails the controller 326 uses the fan failure information to raise the fan speed of the working fans to compensate for the failure. Also note that this controller 326 and its associated hardware may be used in embodiments similar to those shown in FIGS. 1 and 2 if desired.

FIG. 4 is a flow chart of a method for cooling heat-generating devices according to the present invention. The method starts at a step 400. At a step 402, at least one heat spreader is provided. At a step 404, the heat-spreaders are thermally coupled to heat generating devices. At a step 406, at least two fan sinks or at least one double fan sink are provided. At a step 408, the fan sinks are thermally coupled to the heat spreaders. At an optional step 410, a thermal coupling device, such as a heat pipe or copper braid, is provided. At an optional step 412, the thermal coupling device is thermally coupled to the heat spreaders. At an optional step 414, a fan detector is provided for each fan. At an optional step 416, a controller similar to that of FIG. 3 is provided. At an optional step 418, the controller checks the fan detectors for evidence of fan failures. At an optional decision step 420, if no failures are detected control returns to step 418. If a failure is detected, at an optional step 422, power to the failed fan is turned off, and in an optional step 424 the speed of the remaining working fans is increased or idle fans are activated. Optionally, at this point control may be returned to step 418 or the method ends at a finish step 426.

The foregoing description of the present invention has been presented for purposes of illustration and description. It is not intended to be exhaustive or to limit the invention to the precise form disclosed, and other modifications and variations may be possible in light of the above teachings. The embodiments were chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

1. A device, comprising:
a heat spreader thermally coupled to at least one heat-generating device;
a first fan sink thermally coupled to said heat spreader; and
a second fan sink thermally coupled to said heat spreader.

2. The device recited in claim 1,
wherein said first and second fan sinks are configured such that when one fan sink fails the remaining fan sinks maintain the heat-generating devices within their thermal design limits.

3. The device recited in claim 1, further comprising:
at least one heat pipe thermally coupled to said heat spreader.

4. The device recited in claim 1, further comprising:
a first fan detector configured to detect failures of the first fan;
a second fan detector configured to detect failures of the second fan; and
a controller electrically coupled to said first fan detector and said second fan detector including:
a first output electrically coupled to said first fan, configured to control a fan speed of said first fan; and
a second output electrically coupled to said second fan, configured to control a fan speed of said second fan.

5. The device recited in claim 4,
wherein said controller is configured to raise a fan speed of said second fan when a failure of said first fan is detected by said first fan detector; and
wherein said controller is configured to raise a fan speed of said first fan when a failure of said second fan is detected by said second fan detector.

6. A device, comprising:
a heat spreader thermally coupled to at least one heat-generating device; and
a double fan sink thermally coupled to said heat spreader including:
a first fan;
a second fan; and
a heat sink substantially surrounding said first fan and said second fan.

7. The device recited in claim 6,
wherein said first and second fan are configured such that when one fan fails the remaining fan maintains the heat-generating devices within their thermal design limits.

8. The device recited in claim 6, further comprising:
at least one heat pipe thermally coupled to said heat spreader.

9. The device recited in claim 6, further comprising:
a first fan detector configured to detect failures of the first fan;
a second fan detector configured to detect failures of the second fan; and
a controller electrically coupled to said first fan detector and said second fan detector including:
a first output electrically coupled to said first fan, configured to control a fan speed of said first fan; and
a second output electrically coupled to said second fan, configured to control a fan speed of said second fan.

10. The device recited in claim 9,
wherein said controller is configured to raise a fan speed of said second fan when a failure of said first fan is detected by said first fan detector; and
wherein said controller is configured to raise a fan speed of said first fan when a failure of said second fan is detected by said second fan detector.

11. The device recited in claim 9,
wherein said controller is configured to turn on said second fan when a failure of said first fan is detected by said first fan detector; and
wherein said controller is configured to turn on said first fan when a failure of said second fan is detected by said second fan detector.

12. A device, comprising:
a first heat spreader thermally coupled to at least one heat-generating device;
a second heat spreader thermally coupled to at least one heat-generating device and to said first heat spreader;
a first fan sink thermally coupled to said first heat spreader; and
a second fan sink thermally coupled to said second heat spreader.

13. The device recited in claim 12,
wherein said first and second fan sinks are configured such that when one fan sink fails the remaining fan sinks maintain the heat-generating devices within their thermal design limits.

14. The device recited in claim 12, further comprising:
a thermal coupling device thermally coupled to said first heat spreader and said second heat spreader.

15. The device recited in claim 14,
wherein said first and second heat spreaders are non-coplanar; and
wherein said thermal coupling device is flexible.

16. The device recited in claim 15,
wherein said thermal coupling device is a heat pipe.

17. The device recited in claim 15,
wherein said thermal coupling device is constructed of carbon fiber.

18. The device recited in claim 15,
wherein said thermal coupling device is a thermally conductive fabric.

19. The device recited in claim 15,
wherein said thermal coupling device is a copper strap.

20. The device recited in claim 15,
wherein said thermal coupling device is a copper braid.

21. The device recited in claim 12, further comprising:
a first fan detector configured to detect failures of the first fan;
a second fan detector configured to detect failures of the second fan; and
a controller electrically coupled to said first fan detector and said second fan detector including:
a first output electrically coupled to said first fan, configured to control a fan speed of said first fan; and
a second output electrically coupled to said second fan, configured to control a fan speed of said second fan.

22. The device recited in claim 21,
wherein said controller is configured to raise a fan speed of said second fan when a failure of said first fan is detected by said first fan detector; and
wherein said controller is configured to raise a fan speed of said first fan when a failure of said second fan is detected by said second fan detector.

23. The device recited in claim 21,
wherein said controller is configured to turn on said second fan when a failure of said first fan is detected by said first fan detector; and
wherein said controller is configured to turn on said first fan when a failure of said second fan is detected by said second fan detector.

24. A method for cooling heat-generating devices, comprising the steps of:
a) providing a heat spreader;
b) thermally coupling said heat spreader to at least one heat-generating device;
c) providing a first fan sink including a first fan;
d) thermally coupling said first fan sink to said heat spreader;
e) providing a second fan sink including a second fan; and
f) thermally coupling said second fan sink to said heat spreader.

25. The method recited in claim 24,
wherein said first and second fan sinks are configured such that when one fan sink fails the remaining fan sinks maintain the heat-generating devices within their thermal design limits.

26. The method recited in claim 24, further comprising the steps of:
g) providing at least one heat pipe; and
h) thermally coupling said at least one heat pipe to said heat spreader.

27. The method recited in claim 24, further comprising the steps of:
g) providing a first fan detector configured to detect failures of the first fan;
h) providing a second fan detector configured to detect failures of the second fan;
i) providing a controller electrically coupled to said first fan detector and said second fan detector;
j) providing a first output electrically coupled to said first fan;
k) configuring said first output to control a fan speed of said first fan;
(l) providing a second output electrically coupled to said second fan; and
m) configuring said second output to control a fan speed of said second fan.

28. The method recited in claim 27, further comprising the steps of:
n) raising a fan speed of said second fan when a failure of said first fan is detected by said first fan detector; and
o) raising a fan speed of said first fan when a failure of said second fan is detected by said second fan detector.

29. The method recited in claim 28, further comprising the steps of:
p) turning off power to failed fan.

30. The method recited in claim 27, further comprising the steps of:
n) turning on said second fan when a failure of said first fan is detected by said first fan detector; and
o) turning on said first fan when a failure of said second fan is detected by said second fan detector.

31. The method recited in claim 30, further comprising the steps of:
p) turning off power to failed fan.

32. A method for cooling heat-generating devices, comprising the steps of:
a) providing a first heat spreader;
b) thermally coupling said first heat spreader to at least one heat-generating device;
c) providing a second heat spreader;
d) thermally coupling said second heat spreader to at least one heat-generating device;
e) providing a first fan sink including a first fan;
f) thermally coupling said first fan sink to said first heat spreader;
g) providing a second fan sink including a second fan; and
h) thermally coupling said second fan sink to said second heat spreader.

33. The method recited in claim 32,
wherein said first and second fan sinks are configured such that when one fan sink fails the remaining fan sinks maintain the heat-generating devices within their thermal design limits.

34. The method recited in claim 32, further comprising the steps of:
i) providing a thermal coupling device; and
j) thermally coupling said thermal coupling device between said first heat spreader and said second heat spreader.

35. The method recited in claim 34,
wherein said first and second heat spreaders are non-coplanar; and
wherein said thermal coupling device is flexible.

36. The method recited in claim 35,
wherein said thermal coupling device is a heat pipe.

37. The method recited in claim 35,
wherein said thermal coupling device is constructed of carbon fiber.

38. The method recited in claim 35,
wherein said thermal coupling device is a thermally conductive fabric.

39. The method recited in claim 35,
wherein said thermal coupling device is a copper strap.

40. The method recited in claim 35,
wherein said thermal coupling device is a copper braid.

41. The method recited in claim 32, further comprising the steps of:
i) providing a first fan detector configured to detect failures of the first fan;
j) providing a second fan detector configured to detect failures of the second
fan;
k) providing a controller electrically coupled to said first fan detector and said second fan detector;
l) providing a first output electrically coupled to said first fan;
m) configuring said first output to control a fan speed of said first fan;
n) providing a second output electrically coupled to said second fan; and
o) configuring said second output to control a fan speed of said second fan.

42. The method recited in claim 41, further comprising the steps of:
p) raising a fan speed of said second fan when a failure of said first fan is detected by said first fan detector; and
q) raising a fan speed of said first fan when a failure of said second fan is detected by said second fan detector.

43. The method recited in claim 42, further comprising the steps of:
r) turning off power to failed fan.

44. The method recited in claim 41, further comprising the steps of: first fan detector; and
q) turning on said first fan when a failure of said second fan is detected by said second fan detector.

45. The method recited in claim 44, further comprising the steps of:
r) turning off power to failed fan.
